(19) United States
(12) Patent Application Publication
(10) Pub. No.: US 2024/0108540 A1
(43) Pub. Date: Apr. 4, 2024

(54) VIBRATION CAPSULE

(71) Applicants: Ankon Medical Technologies(Shanghai) Co., LTD, Shanghai (CN); ANX IP HOLDING PTE. LTD., SG (SG)

(72) Inventors: Fang WANG, Shanghai (CN); Xiaodong Duan, Pleasanton, CA (US)

(21) Appl. No.: 18/479,060

(22) Filed: Sep. 30, 2023

(30) Foreign Application Priority Data
Sep. 30, 2022 (CN) 202211211380.4

(51) Int. Cl. A61H 23/02

(52) U.S. Cl. CPC A61H 23/02; A61H 2205/00

(57) ABSTRACT

The present invention discloses a vibration capsule, including: an enclosure, a vibration motor, a battery assembly, and a control assembly. The vibration motor, the battery assembly and the control assembly are disposed within the enclosure, the vibration motor and the battery assembly are electrically connected to the control assembly. The control assembly includes a first PCB and a second PCB, disposed at opposite ends of the battery assembly, a connecting structure that connects the first PCB and the second PCB, and a plurality of electronic devices disposed on one side of the first PCB away from the battery assembly, and/or on one side of the second PCB away from the battery assembly. The present invention achieves that there is no relative tilt between the control assembly and the battery assembly, ensuring coaxial alignment between the control assembly and the battery assembly.

### FIELD OF INVENTION

The present invention relates to a medical device, and more particularly to a vibration capsule.

### BACKGROUND

A vibration capsule is a device designed for the treatment of chronic functional constipation. Upon ingestion by a patient, the vibration capsule continuously vibrates, shakes, and rolls as it passes through the intestinal tract. This motion stimulates the muscles, prompting the intestinal tract to restart natural peristalsis, thereby alleviating the symptoms of constipation.

The vibration capsule typically includes an enclosure, a vibration motor, a control assembly, and a battery assembly. The vibration motor, the battery assembly and the control assembly are all disposed within the enclosure, and the vibration motor and the battery assembly are electrically connected to the control assembly. The control assembly includes a PCB (Printed Circuit Board) and electronic devices mounted on the PCB. Due to variations in the height of the electronic devices, if the contact surfaces of the electronic devices and the battery assembly are only affixed by insulation sheets during assembly of the vibration capsule, tilting may be caused, thus a coaxiality between the control assembly and the battery assembly cannot be ensured. Such misalignment may cause significant disruptions during assembly and decrease the yield rate of the vibration capsule.

### SUMMARY OF THE INVENTION

It is an object of the present invention to provide a vibration capsule configured with PCBs at both ends of a battery assembly.

To achieve one of the above objects of the present invention, an embodiment of the present invention provides a vibration capsule comprising: an enclosure; a vibration motor; a battery assembly; and a control assembly. The vibration motor, the battery assembly and the control assembly are disposed within the enclosure, and the vibration motor and the battery assembly are electrically connected to the control assembly. The control assembly comprises a first PCB and a second PCB, disposed at opposite ends of the battery assembly; a connecting structure that connects to the first PCB and the second PCB; and a plurality of electronic devices disposed on one side of the first PCB away from the battery assembly, and/or on one side of the second PCB away from the battery assembly.

In some embodiments, the first PCB and the second PCB are parallel to each other, the two ends of the connecting structure are respectively connected to the edges of the first PCB and the second PCB, and the connecting structure is disposed at a side of the battery assembly.

In some embodiments, the connecting structure is a flexible PCB.

In some embodiments, the battery assembly comprises a battery unit, a first connector connected to one end of the battery unit facing the first PCB, and a second connector connected to one end of the battery unit facing the second PCB. The first connector is electrically connected to the first PCB and the second connector is electrically connected to the second PCB.

In some embodiments, the first connector comprises a first main body portion that is parallel to the first PCB and first extension portions extending from two ends of the first main body portion in a direction away from the battery unit. The first main body portion is connected to one end of the battery unit facing the first PCB, and the first extension portions are soldered to the first PCB. The second connector comprises a second main body portion that is parallel to the second PCB and second extension portions extending from two ends of the second main body portion in a direction away from the battery unit. The second main body portion is connected to one end of the battery unit facing the second PCB, and the second extension portions are soldered to the second PCB.

In some embodiments, the first PCB is configured with two first through-holes that correspond one-to-one with the first extension portions, the first main body portion is fitted onto the first PCB, and the first extension portions extend into the first through-holes. The second PCB is configured with two second through-holes that correspond one-to-one with the second extension portions, the second main body portion is fitted onto the second PCB, and the second extension portions extend into the second through-holes.

In some embodiments, the battery unit comprises a battery body and a cathode protrusion extending from one side of the battery body close to the first main body portion, toward the first main body portion. The battery assembly further comprises an insulation ring that surrounds the cathode protrusion, and the insulation ring is disposed between the first main body portion and the battery body.

In some embodiments, the vibration motor, the first PCB, the battery assembly, and the second PCB are arranged sequentially along the axial direction of the enclosure. The vibration capsule further comprises a motor bracket for securing the vibration motor, and the motor bracket is connected to the inner wall of the enclosure. The motor bracket comprises a first fixing portion that fits with the vibration motor and a second fixing portion that fits with the first PCB.

In some embodiments, one end of the first fixing portion facing the first PCB abuts against the first PCB. The first fixing portion comprises a holding cavity for housing the vibration motor.

In some embodiments, the second fixing portion comprises a plurality of fixing rods extending in a direction parallel to the axial direction of the enclosure. The plurality of fixing rods surround the first PCB, and the outer periphery of the first PCB is configured with fixing grooves that fit with the fixing rods. Ends of the fixing rods away from the first fixing portion abut against the battery assembly.

In some embodiments, the groove wall of the fixing groove is arc-shaped.

In some embodiments, the vibration capsule further comprises a motor bracket and an antenna. The motor bracket is for securing the vibration motor, and the antenna is fixed to the motor bracket. The antenna is communicatively connected to the first PCB and/or the second PCB.

In some embodiments, the antenna comprises a planar antenna and/or a wire antenna.

In some embodiments, the motor bracket comprises an adhesive portion for adhering the planar antenna and/or an antenna groove for securing the wire antenna. The antenna groove comprises a first antenna groove extending axially along the motor bracket and a second antenna groove disposed at one end of the motor bracket, away from the battery assembly.

In some embodiments, the vibration capsule further comprises a motor cover disposed on one end of the motor bracket, away from the battery assembly.

According to the embodiments of the present invention, electronic devices are arranged on only one side of the first PCB and the second PCB, with the side not containing electronic devices in contact with the battery assembly, and the first PCB is connected to the second PCB using a connecting structure, so that the present invention achieves the connection of electronic devices to the PCBs in a confined internal space of the vibration capsule, and no relative tilting between the control assembly and the battery assembly, which ensures coaxial alignment between the control assembly and the battery assembly. Such construction facilitates the assembly of the vibration capsule and improves its yield rate.

### BRIEF DESCRIPTION OF THE DRAWINGS

FIG. 1 is a structural schematic diagram of a vibration capsule according to a first embodiment of the present invention.

FIG. 2 is a structural schematic diagram of the vibration capsule with its enclosure hidden according to the first embodiment of the present invention.

FIG. 3 is a sectional view along the line A-A′ in FIG. 2.

FIG. 4 is a sectional view along the line B-B′ in FIG. 2.

FIG. 5 is a structural schematic diagram of a control assembly and a battery assembly at a first angle of view according to the first embodiment of the present invention.

FIG. 6 is a structural schematic diagram of the control assembly and battery assembly at a second angle of view according to the first embodiment of the present invention.

FIG. 7 is a sectional view along the line C-C′ in FIG. 6.

FIG. 8 is a structural schematic diagram of the control assembly according to the first embodiment of the present invention.

FIG. 9 is a structural schematic diagram of the battery assembly according to the first embodiment of the present invention.

FIG. 10 is a structural schematic diagram of a motor bracket according to the first embodiment of the present invention.

FIG. 11 is a structural schematic diagram of a first fitting structure between an antenna, the control assembly and the motor bracket according to the first embodiment of the present invention.

FIG. 12 is a structural schematic diagram of a second fitting structure between the antenna, the control assembly and the motor bracket according to the first embodiment of the present invention.

FIG. 13 is a structural schematic diagram of the vibration capsule with part of its enclosure hidden according to a second embodiment of the present invention.

FIG. 14 is a sectional view along the line D-D′ in FIG. 13.

FIG. 15 is a sectional view along the line F-F′ in FIG. 13.

FIG. 16 is a top view of the control assembly according to the second embodiment of the present invention.

FIG. 17 is a structural schematic diagram of a power supply assembly at a first angle of view according to the second embodiment of the present invention.

FIG. 18 is a structural schematic diagram of the power supply assembly at a second angle of view according to the second embodiment of the present invention.

FIG. 19 is a structural schematic diagram of the power supply assembly at a third angle of view according to the second embodiment of the present invention.

10-enclosure; 20-control assembly; 21-first PCB; 211-first through-hole; 212-fixing groove; 22-second PCB; 221-second through-hole; 23-connecting structure; 231-vertical section; 232-connecting section; 24-electronic devices; 25-PCB; 26-first soldering portion; 27-second soldering portion; 30-battery assembly; 31-battery unit; 311-battery body; 312-cathode protrusion; 313-first battery; 314-second battery; 32-first connector; 321-first main body portion; 322-first extension portion; 33-second connector; 331-second main body portion; 332-second extension portion; 34-insulation ring; 35-intermediate connector; 351-end face; 352-side edge; 353-soldering lug; 354-avoidance opening; 36-first insulating member; 37-second insulating member; 38-third connector; 381-third main body portion; 382-third extension portion; 39-fourth connector; 391-fourth main body portion; 392-fourth extension portion; 40-vibration motor; 50-motor bracket; 51-first fixing portion; 511-holding cavity; 512-first avoidance groove; 513-second avoidance groove; 52-second fixing portion; 521-fixing rod; 53-antenna groove; 531-first antenna groove; 532-second antenna groove; 54-motor cover; 55-flange; 60-antenna; 61-planar antenna; 62-wire antenna.

### DETAILED DESCRIPTION

The present invention can be described in detail below with reference to the accompanying drawings and preferred embodiments. However, the embodiments are not intended to limit the present invention, and the structural, method, or functional changes made by those skilled in the art in accordance with the embodiments are included in the scope of the present invention.

In various illustrations of the present invention, for the purpose of clarity, certain dimensions of the structure or components may be magnified relative to other structures or components. Therefore, these magnifications are solely for the illustration of the fundamental structure of the subject matter of the present invention.

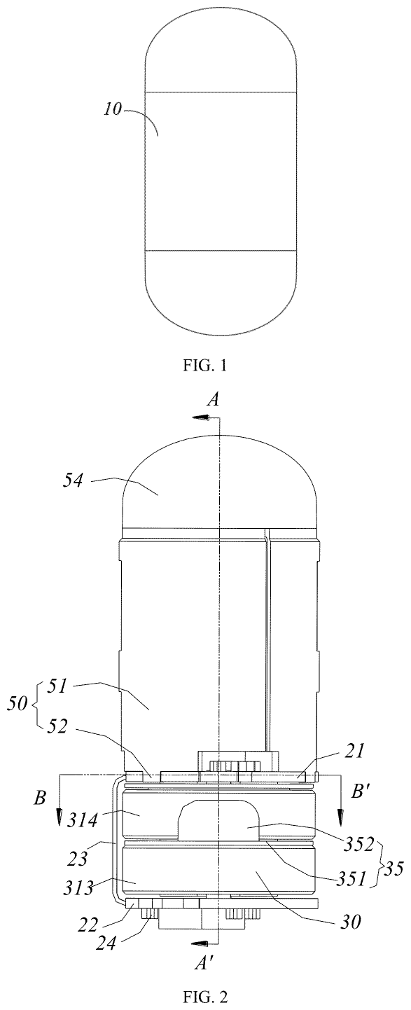

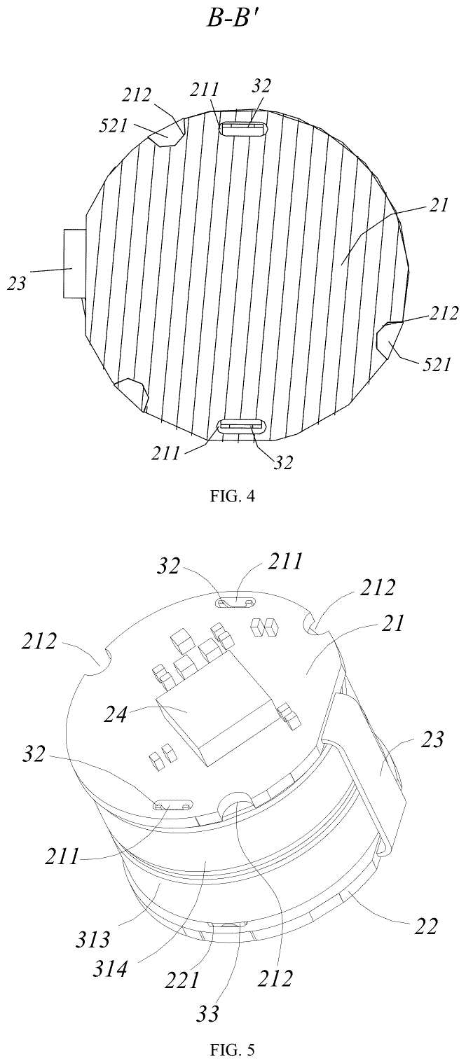

Referring to FIGS. 1, 2, 3 and 4, the present invention provides a vibration capsule comprising an enclosure 10, a control assembly 20, a battery assembly 30 and a vibration motor 40.

The enclosure 10 is made of a biocompatible material, and the enclosure 10 comprises an internal cavity. The enclosure 10 is constructed by joining a plurality of components for the convenience of assembling the vibration capsule.

The control assembly 20, the battery assembly 30 and the vibration motor 40 are all disposed within the enclosure 10, and both the vibration motor 40 and the battery assembly 30 are electrically connected to the control assembly 20. The vibration motor 40 vibrates when activated, and the vibration drives the overall vibration capsule to vibrate, thereby stimulating the muscles of a user and prompting the intestinal tract to restart its natural peristalsis, relieving symptoms of constipation.

The control assembly 20 comprises one or more PCBs (Printed Circuit Board) 25 and a plurality of electronic devices 24. The present invention categorizes the vibration capsule into two types based on the number of PCBs.

In a first embodiment corresponding to a first type, the control assembly 20 comprises a first PCB 21 and a second PCB 22, which are respectively disposed at two ends of the battery assembly 30, and a connecting structure 23 that connects the first PCB 21 and the second PCB 22.

The electronic devices 24 comprise, but are not limited to, chips. The plurality of electronic devices 24 are only disposed on the side of the first PCB 21 away from the battery assembly 30 and/or on the side of the second PCB 22 away from the battery assembly 30. In other words, some electronic devices 24 are disposed on the side of the first PCB 21 away from the battery assembly 30, and/or the remaining electronic devices 24 are disposed on the side of the second PCB 22 away from the battery assembly 30. No electronic devices 24 are disposed on the sides of the first PCB 21 and the second PCB 22 that face towards the battery assembly 30.

According to the embodiment of the present invention, the electronic devices 24 are arranged on only one side of the first PCB 21 and the second PCB 22, with the side not arranging electronic devices 24 in contact with the battery assembly 30, and the first PCB 21 is connected to the second PCB 22 using the connecting structure 23, so that the present invention achieves the connection of the electronic devices 24 to the PCBs 25 in a confined internal space of the vibration capsule, and no relative tilting between the control assembly 20 and the battery assembly 30, which ensures coaxial alignment between the control assembly 20 and the battery assembly 30. Such construction facilitates the assembly of the vibration capsule and improves its yield rate. In addition, the sides of the first PCB 21 and the side of the second PCB 22 that are in contact with the battery assembly 30 do not need to have circuits and can serve as an insulation layer, thus reducing the amount of insulation material required for the vibration capsule, simplifying the structure, and lowering cost.

Referring to FIGS. 1-3, the vibration motor 40, the first PCB 21, the battery assembly 30, and the second PCB 22 are arranged sequentially along the axial direction of the enclosure 10.

Referring to FIGS. 2, 3, 5, 6 and 7, specifically, the first PCB 21 is parallel to the second PCB 22. Two ends of the connecting structure 23 is connected to the edges of the first PCB 21 and the second PCB 22. The connecting structure 23 is disposed at the side of the battery assembly 30. This arrangement prevents the connecting structure 23 from occupying space between the first PCB 21 and the second PCB 22, allowing for easier insertion of the battery assembly 30 between the first PCB 21 and the second PCB 22.

The connecting structure 23 is a flexible PCB, and it facilitates the electrical connection between the first PCB 21 and the second PCB 22. Due to its flexibility, the connecting structure 23 can deform when an operator applies a force to it. When no force is applied to the connecting structure 23, it can maintain its deformed shape.

When the operator needs to assemble the battery assembly 30, they apply opposite forces to the first PCB 21 and the second PCB 22. This deformation of the connecting structure 23 increases the distance between the area on the edge of the first PCB 21 away from the connecting structure 23 and the area on the edge of the second PCB 22 away from the connecting structure 23. This makes it easier to place the battery assembly 30 between the first PCB 21 and the second PCB 22. Then, the operator applies force again to the first PCB 21 and the second PCB 22, causing them to have a close contact with two ends of the battery assembly 30. At this point, the first PCB 21 and the second PCB 22 securely hold the battery assembly 30 and provide some degree of positioning for it.

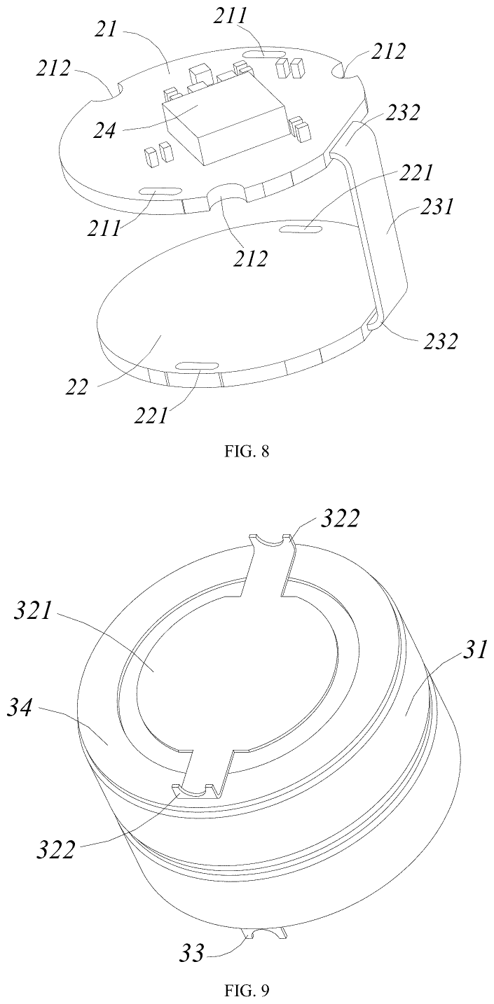

Referring to FIG. 8, further, the connecting structure 23 comprises a vertical section 231 and connecting sections 232 attached to two ends of the vertical section 231. The connecting sections 232 have a certain angle relative to the vertical section 231. Operators can change the relative positions of the first PCB 21 and the second PCB 22 by altering the angle between the connecting sections 232 and the vertical section 231. The angle is determined by the bending radius of the connecting structure 23 and should generally not be too small to avoid breakage.

The thickness of the connecting structure 23 is smaller than the thickness of the first PCB 21 and the second PCB 22, making it easy to adjust. The connecting structure 23 does not protrude beyond the first PCB 21 and the second PCB 22, preventing the battery assembly 30 from tilting due to contact with the connecting structure 23.

The first PCB 21 comprises a solder pad (not shown in FIGs) for connecting to two wires (not shown in FIGs) of the vibration motor 40. The two wires of the vibration motor 40 do not need to cross over the battery assembly 30 or pass through the space between the battery assembly 30 and the inner wall of the enclosure 10, making assembly of the vibration capsule more convenient.

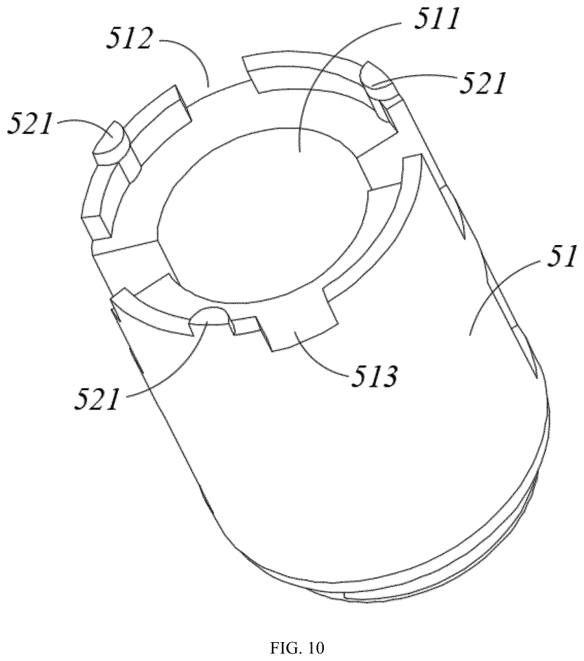

Referring to FIGS. 5, 6, 7 and 9, in an embodiment of the present invention, the battery assembly 30 comprises a battery unit 31, a first connector 32, a second connector 33 and an insulation ring 34. The first connector 32 and the second connector 33 are made of metal materials.

The battery unit 31 provides the necessary energy for the operation of various components within the enclosure 10. The battery unit 31 may comprise a single battery or be composed of at least two batteries in series. Preferably, the battery is a silver oxide battery.

For illustration purposes, the present invention takes the case where the battery unit 31 comprises two batteries as an example to explain the electrical connection between the battery unit 31, the first connector 32, the second connector 33, the first PCB 21, and the second PCB 22. The description also applies to the case where the two batteries shown in the diagram are replaced with a single battery.

The first connector 32 is connected to one end of the battery unit 31 facing the first PCB 21 and is electrically connected to the first PCB 21. The second connector 33 is connected to one end of the battery unit 31 facing the second PCB 22 and is electrically connected to the second PCB 22. The first connector 32 and the second connector 33 enable electrical continuity between the battery unit 31 and the control assembly 20. Since the two wires of the vibration motor 40 are connected to the first PCB 21, the battery assembly 30 can provide power to the vibration motor 40 through the control assembly 20.

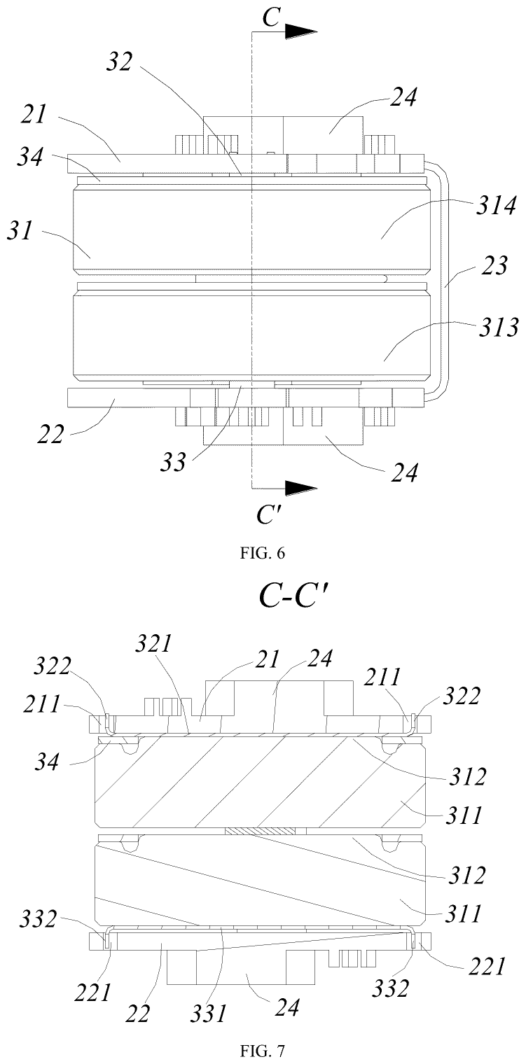

Referring to FIGS. 6, 7 and 9. the first connector 32 comprises a first main body portion 321 that is parallel to the first PCB 21 and first extension portions 322 extending from two ends of the first main body portion 321 in a direction away from the battery unit 31. The first main body portion 321 is connected to one end of the battery unit 31 facing the first PCB 21, and the first extension portions 322 are used for soldering to the first PCB 21. The two first extension portions 322 are soldered to the first PCB 21, ensuring a secure and reliable connection between the first PCB 21 and the battery assembly 30.

The first PCB 21 is configured with two first through-holes 211 that correspond one-to-one with the first extension portions 322, the first main body portion 321 is fitted onto the first PCB 21, and the first extension portions 322 extend into the first through-holes 211. When the first extension portions 322 extend into the first through-holes 211, operators can solder the first extension portions 322 to the first PCB 21, thereby connecting the battery assembly 30 to the first PCB 21.

The second connector 33 comprises a second main body portion 331 that is parallel to the second PCB 22 and second extension portions 332 extending from two ends of the second main body portion 331 in a direction away from the battery unit 31. The second main body portion 331 is connected to one end of the battery unit 31 facing the second PCB 22, and the second extension portions 332 are used for soldering to the second PCB 22. The two second extension portions 332 are soldered to the second PCB 22, ensuring a secure and reliable connection between the second PCB 22 and the battery assembly 30.

The second PCB 22 is configured with two second through-holes 221 that correspond one-to-one with the second extension portions 332, the second main body portion 331 is fitted onto the second PCB 22, and the second extension portions 332 extend into the second through-holes 221. When the second extension portions 332 extend into the second through-holes 221, operators can solder the second extension portions 332 to the second PCB 22, thereby connecting the battery assembly 30 to the second PCB 22.

Therefore, the first connector 32 is soldered to the first PCB 21, and the second connector 33 is soldered to the second PCB 22, thus forming an integrated structure of the battery assembly 30 and the control assembly 20.

Specifically, the first extension portions 322 extend in a direction perpendicular to the first main body portion 321, and the second extension portions 332 extend in a direction perpendicular to the second main body portion 331. The first main body portion 321 and the first extension portions 322 form an integral structure, and the second main body portion 331 and the second extension portions 332 form an integral structure.

The battery unit 31 comprises a battery body 311 and a cathode protrusion 312 extending from one side of the battery body 311 close to the first main body portion 321, toward the first main body portion 321. The insulation ring 34 surrounds the cathode protrusion 312 and is disposed between the first main body portion 321 and the battery body 311. The insulation ring 34 is used to prevent the first main body portion 321 from coming into contact with the battery body 311, thereby preventing a short circuit between the anode and cathode of the battery unit 31.

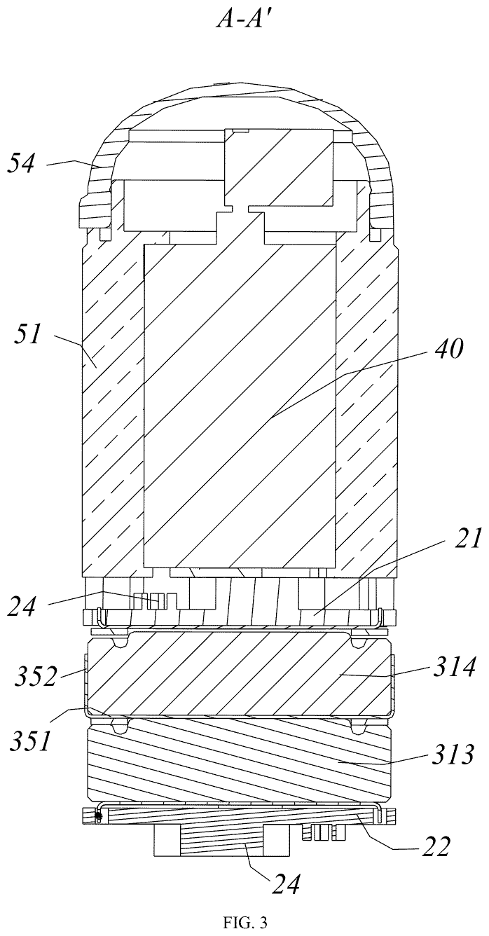

Preferably, as shown in FIGS. 2 and 3, the battery unit 31 comprises a first battery 313 and a second battery 314, where the anode of the second battery 314 is connected to the cathode of the first battery 313, and the first battery 313 and the second battery 314 are both preferably a button battery.

The first battery 313 and the second battery 314 are electrically connected through an intermediate connector 35. Specifically, the intermediate connector 35 comprises an end face 351 and at least two side edges 352 extending vertically to one side from the end face 351. The end face 351 is riveted to the cathode of the first battery 313, and the side edges 352 are riveted to the side anode of the second battery 314, connecting the first battery 313 and the second battery 314 into a whole unit.

Additionally, the first connector 32 is riveted to the cathode end face of the second battery 314, connecting the cathode of the battery assembly 30 to the first PCB 21, and the second connector 33 is riveted to the anode end face of the first battery 313, connecting the anode of the battery assembly 30 to the second PCB 22.

In the embodiment, the riveting process uses a laser riveting technique.

Referring to FIGS. 2, 3, 4 and 10, in an embodiment of the present invention, the vibration capsule further comprises a motor bracket 50.

The motor bracket 50 is used to secure the vibration motor 40, and it is connected to the inner wall of the enclosure 10. Specifically, the outer periphery of the motor bracket 50 is provided with slots, and the inner wall of the enclosure 10 comprises blocks that engage with the slots.

The motor bracket 50 comprises a first fixing portion 51 that fits with the vibration motor 40 and a second fixing portion 52 that fits with the first PCB 21. By fixing the first PCB 21 with the motor bracket 50, the vibration motor 40, the control assembly 20, and the battery assembly 30 are connected as a whole, eliminating the need for additional components to secure the control assembly 20. This simplifies the structure, reduces costs, decreases the number of production and assembly steps, improves structural stability, and enhances the utilization of space inside the capsule, preventing overcrowding.

One end of the first fixing portion 51 facing the first PCB 21 abuts against the first PCB 21. The first fixing portion 51 is internally hollow, forming a holding cavity 511 for housing the vibration motor 40. Further, the inner wall of the holding cavity 511 grips the vibration motor 40.

During the assembly of the vibration capsule, due to the uneven surface of the electronic devices 24, the control assembly 20 and the vibration motor 40 may tilt, which affects the coaxiality of the internal structure of the vibration capsule. With the above solution, during assembly, the vibration motor 40 is first placed in the holding cavity 511, and then fixed using the first fixing portion 51, to prevent the vibration motor 40 from tilting. Then, the first PCB 21 is fitted with the second fixing portion 52. The end of the first fixing portion 51 abuts against the first PCB 21, preventing the control assembly 20 from tilting relative to the vibration motor 40 and the motor bracket 50.

The second fixing portion 52 comprises a plurality of fixing rods 521 that extend axially in parallel with the enclosurel0 and surround the first PCB 21. The fixing rods 521 are used to fit with the first PCB 21 to limit the radial movement of the control assembly 20 along the enclosure 10. The outer periphery of the first PCB 21 is provided with fixing grooves 212 that fit with the fixing rods 521, and the ends of the fixing rods 521 away from the first fixing portion 51 abut against the battery assembly 30.

The motor bracket 50 fits with the control assembly 20 in a process as follows. The operator moves the control assembly 20 relative to the motor bracket 50, allowing the fixing rods 521 to pass through the fixing grooves 212 until the end of the first fixing portion 51 abuts against the surface of the first PCB 21. Then, adhesive is applied to secure the first PCB 21 to the motor bracket 50, preventing the first PCB 21 from disengaging from the motor bracket 50 along the axial direction of the enclosure 10.

Further, the groove wall of the fixing grooves 212 is arc-shaped, meaning that the projection of the fixing grooves 212 on the surface of the first PCB 21 is arc-shaped, and the fixing grooves 212 have no sharp corners, making it easier for the fixing rods 521 to fit with the fixing grooves 212.

Further, the first fixing portion 51 is provided with a first avoidance groove 512 and a second avoidance groove 513, and the first avoidance groove 512 and the second avoidance groove 513 correspond to the two first through-holes 211, respectively. The first avoidance groove 512 and the second avoidance groove 513 provide space required for the soldering process of connecting the first extension portions 322 to the first PCB 21.

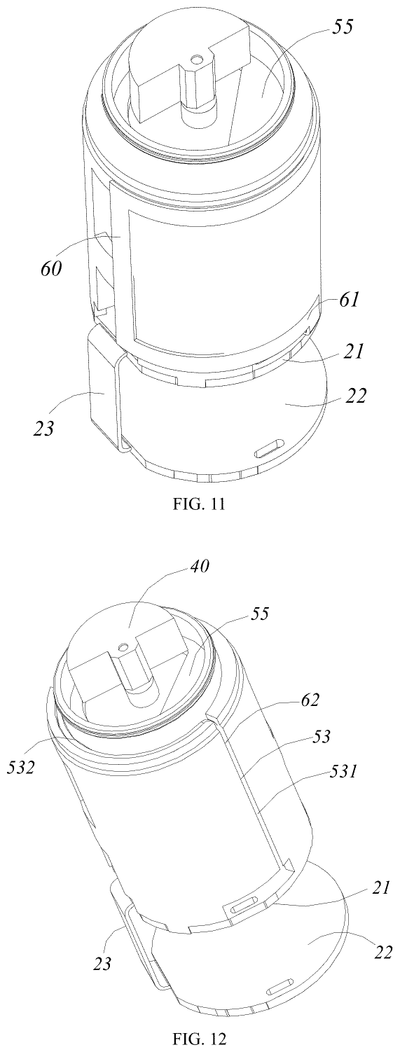

Referring to FIG. 2, and FIGS. 11-12, the vibration capsule of the present invention also comprises an antenna 60 for transmitting signals to external devices. The antenna 60 comprises a planar antenna 61 (or patch antenna) and/or a wire antenna 62. The antenna 60 is fixed to the motor bracket 50, and the antenna 60 is communicatively connected to the first PCB 21 and/or the second PCB 22.

The outer surface of the motor bracket 50 comprises an adhesive portion for adhering the planar antenna 61. The adhesive portion is a smooth surface to enhance adhesion reliability. The planar antenna 6 adhered to the outer surface of the motor bracket 50 and soldered to a solder pad pre-reserved on the first PCB 21. The back of the planar antenna 61 may comprise a self-adhesive layer or may be coated with adhesive during the adhering process.

The wire antenna 62 is preferably a copper wire antenna and is clamped in an antenna groove 53 of the motor bracket 50 to prevent it from popping out during use, thereby improving installation reliability. It is also soldered to the solder pad pre-reserved on the first PCB 21. In the present invention, the antenna groove 53 comprises a first antenna groove 531 extending axially along the motor bracket 50 and a second antenna groove 532 disposed at one end of the motor bracket 50, away from the battery assembly 30. The second antenna groove 532 is arranged circumferentially around the motor bracket 50 and is generally annular in shape.

Preferably, the vibration capsule further comprises a motor cover 54 disposed at one end of the motor bracket 50 away from the battery assembly 30, for enclosing the wire antenna 62 in the second antenna groove 532, so that the wire antenna 62 cannot pop out, making the installation of the wire antenna 62 more reliable. In addition, the motor cover 54 blocks the bottom fragmented components, making the overall appearance more aesthetic.

Further, in the present invention, the motor bracket 50 is also provided with an inwardly extending flange 55 on the end of the motor bracket 50 away from the battery assembly 30 to achieve axial limit of the vibration motor 40. The vibration motor 40 is preferably an eccentric wheel motor. The design of the flange 55 fully utilizes the gap position between the motor body and the eccentric wheel to achieve the axial position limit, making the structure compact.

The assembly process of the internal structure of the vibration capsule according to one embodiment of the present invention is as follows:
(1) fitting the vibration motor 40 into the cavity 511 so that the vibration motor 40 is fixed to the motor bracket 50, then using adhesive to bond the vibration motor 40 to the motor bracket 50 to reinforce their connection; in the embodiments with the antenna 60, the antenna 60 is also fixed to the motor bracket 50 at the same time;
(2) placing the battery assembly 30 between the first PCB 21 and the second PCB 22, then soldering the first extension portions 322 to the first PCB 21 and the second extension portions 332 to the second PCB 22;
(3) moving the assembly from step (1) relative to the assembly from step (2) to allow the fixing rods 521 of the second fixing portion 52 to pass through the fixing grooves 212 of the first PCB 21 until the end of the first fixing portion 51 abuts against the surface of the first PCB; then, using adhesive to reinforce the connection between the first PCB 21 and the motor bracket 50, so that the control assembly 20, the battery assembly 30, the vibration motor 40, and the motor bracket 50 are connected together;
(4) soldering the two wires of the vibration motor 40 and the antenna 60 to the solder pads on the first PCB 21.

By the above steps, the control assembly 20, the battery assembly 30, the vibration motor 40, and the motor bracket 50 are connected together to form a cohesive structure that enhances the stability of the internal components of the vibration capsule. The assembled structure is then placed inside the enclosure 10 to complete the assembly of the entire vibration capsule. Since the two wires of the vibration motor 40 do not cross over the battery assembly 30, the width of the overall structure at the battery assembly 30 does not increase, making it easier for the overall structure to be installed into the enclosure 10.

In another embodiment of the present invention, the electronic devices 24 may also comprise a reed switch. Other parts are the same as the previous embodiment.

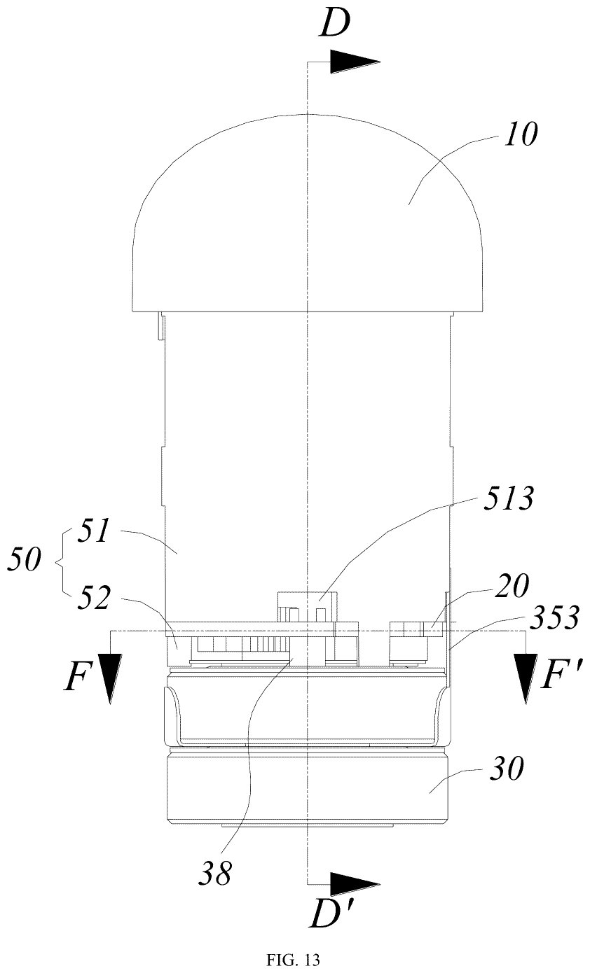

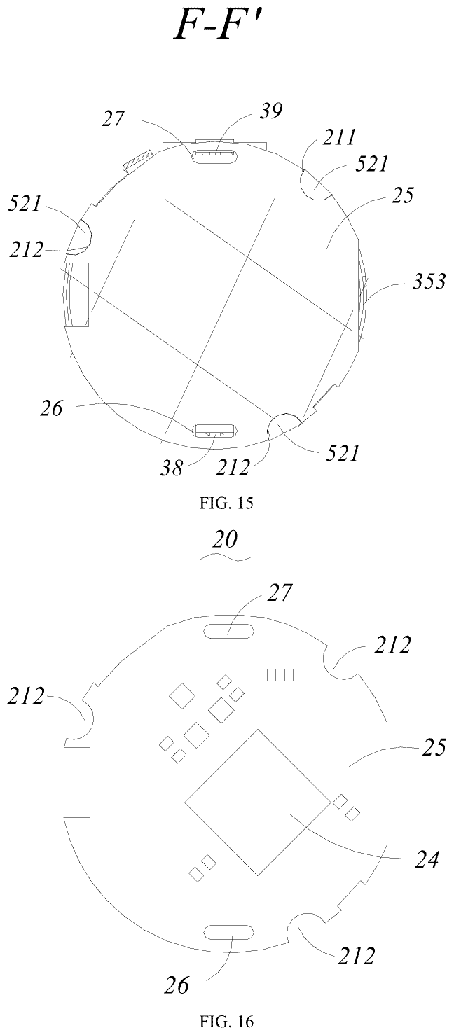

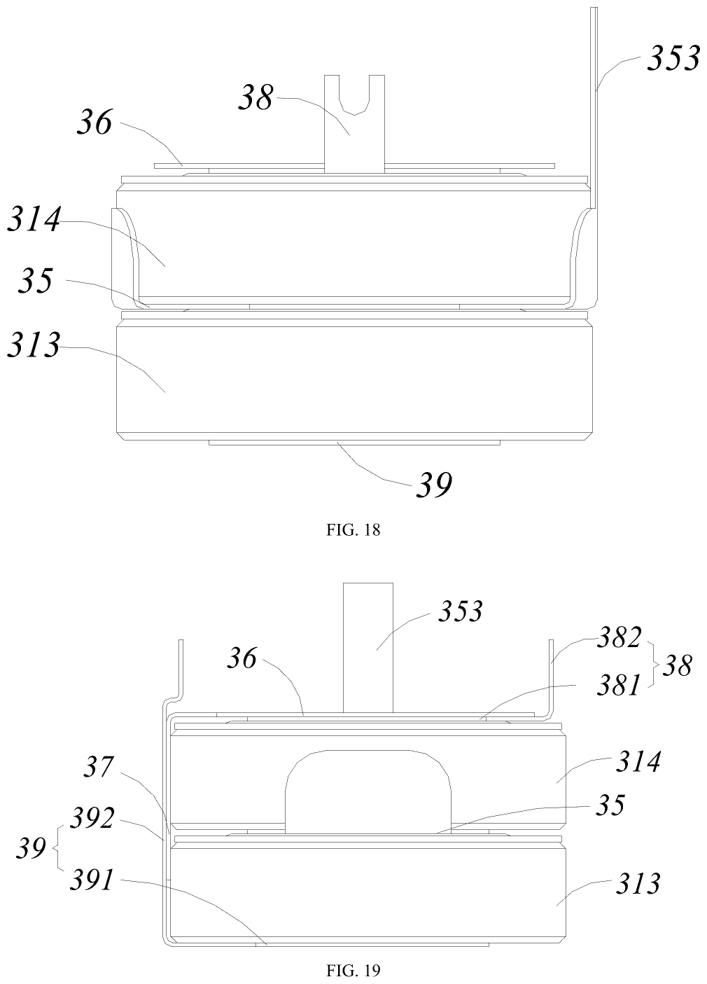

Referring to FIGS. 13-19, the present invention further provides a second embodiment regarding the second type. The main difference from the first embodiment regarding the first type is that: the control assembly 20 comprises only one PCB 25, and depending on the number of electronic devices 24, the electronic devices 24 can be installed on one or both sides of the PCB 25. Based on this, the fitting design between the control assembly 20 and the battery assembly 30 is modified accordingly, and the following detailed description is provided below. In the embodiments, the structural design of the motor bracket and antenna is similar to that of the first embodiment regarding the first type. Please refer to the relevant description and drawings of first embodiment regarding the first type for details, and they are not repeated here.

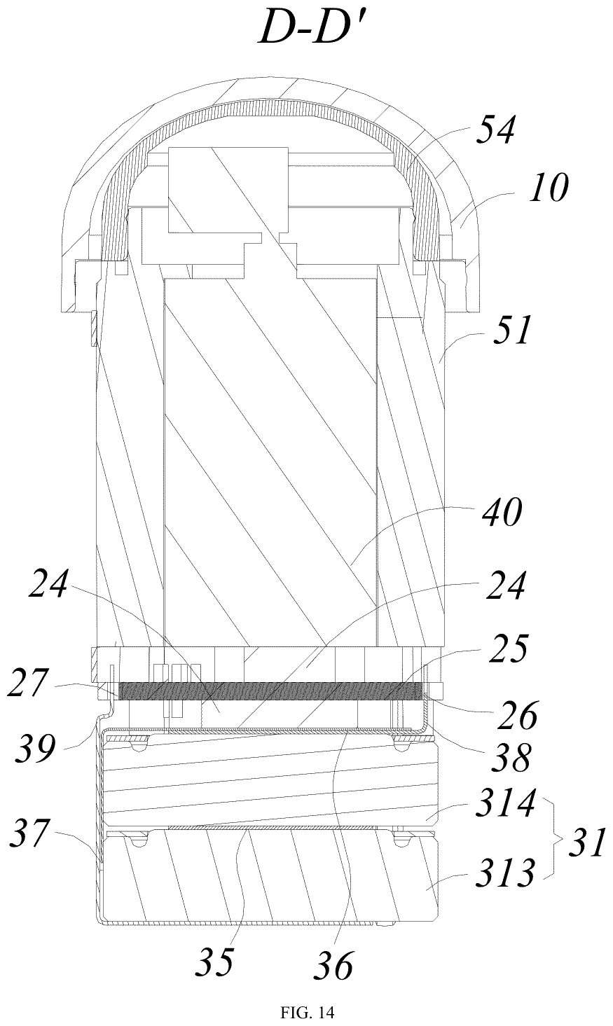

Referring to FIGS. 13-14, the vibration motor 40, the PCB 25, the battery assembly 30 are arranged sequentially along the axial direction of the enclosure 10. The arrangement position of the PCB 25 is similar to the first PCB 21 in the first embodiment.

During the assembly of the vibration capsule, due to the uneven surface of the electronic devices 24, the control assembly 20 and the vibration motor 40 may tilt, making it impossible to ensure the coaxiality of the internal structure of the vibration capsule, which can greatly interfere with the assembly process and seriously affect the yield of the vibration capsule. To solve this technical problem, the present invention adopts the following solution.

Referring to FIGS. 13-16, the motor bracket 50 comprises a first fixing portion 51 that fits for installing the vibration motor 40 and a second fixing portion 52 that fits for assembling the control assembly 20.

Similar to the first embodiment, referring to FIG. 10, the first fixing portion 51 comprises a holding cavity 511 internally, and the inner wall of the cavity 511 grips the vibration motor 40, and the end of the first fixing portion 51 abuts against the PCB 25.

Further, the cavity 511 comprises an opening facing the PCB 25, which can avoid the electronic devices 24 disposed on the side of the PCB 25 facing the vibration motor 40 and allow the wires connecting the vibration motor 40 and the PCB 25 to pass through.

The second fixing portion 52 comprises a plurality of fixing rods 521 that extend axially in parallel with the enclosurel0 and surround the PCB 25. The fixing rods 521 are used to fit with the PCB 25 to limit the radial movement of the control assembly 20 along the enclosure 10.

As illustrated in FIGS. 13-16, and referring to FIG. 10, the outer periphery of the PCB 25 is provided with fixing grooves 212 that fit with the fixing rods 521. The second fixing portion 52 fits with the control assembly 20 in a process as follows: the operator moves the control assembly 20 relative to the motor bracket 50, allowing the fixing rods 521 to pass through the fixing grooves 212 of the PCB 25 until the end of the first fixing portion 51 abuts against the surface of the PCB 25; then, adhesive is applied to secure the PCB 25 to the motor bracket 50, preventing the PCB 25 from disengaging from the motor bracket 50 along the axial direction of the enclosure 10.

Specifically, the groove wall of the fixing grooves 212 is arc-shaped, meaning that the projection of the fixing grooves 212 on the surface of the PCB 25 is arc-shaped, and the fixing grooves 212 have no sharp corners, making it easier for the fixing rods 521 to fit with the fixing grooves 212.

In the present invention, the vibration motor 40 is first placed in the holding cavity 511, and then the vibration motor 40 is fixed using the first fixing portion 51 to prevent the vibration motor 40 from tilting. Then, the control assembly 20 fits with the second fixing portion 52. The end of the first fixing portion 51 abuts against the surface of the PCB 25, preventing the control assembly 20 from tilting.

By simultaneously installing and positioning the vibration motor 20 and the control assembly 20 on the motor bracket 50, the structure is simplified, reducing costs, streamlining production and assembly processes, enhancing structural stability, and improving space utilization inside the vibration capsule. This design also helps prevent overcrowding of internal components within the vibration capsule.

Referring to FIGS. 13-16, in an embodiment of the present invention, both sides of the PCBs are used for installing the electronic devices 24, and the PCB 25 also comprises solder pads for connecting to the wires of the vibration motor 40, the battery assembly 30, the antenna 60, and other components.

Referring to FIGS. 13-14 and 17-19, in an embodiment of the present invention, the battery assembly 30 comprises a battery unit 31, connectors, an intermediate connector 35, a first insulation member 36 and a second insulation member 37. The battery unit 31 comprises at least one battery. Preferably, the battery is a silver oxide button battery.

Specifically, the connectors comprise a third connector 38, which is connected to one end of the battery unit 31 facing the PCB 25, and a fourth connector 39, which is connected to the end of the battery unit 31 opposite to the PCB 25. The third connector 38 and the fourth connector 39 are made of metal materials.

The third connector 38 and the fourth connector 39 extend towards the vibration motor 40. Referring to FIGS. 13-16, the PCB 25 comprises a first soldering portion 26 for soldering with the third connector 38 and a second soldering portion 27 for soldering with the fourth connector 39. The electrical connection and secure attachment of the battery assembly 30 to the control assembly 20 are achieved through the soldering of the third connector 38 to the first soldering portion 26 and the soldering of the fourth connector 39 to the second soldering portion 27. Indeed, the fact that the soldering of the battery assembly 30 to the control assembly 20 is performed on the same side of the battery assembly 30 contributes to a more robust and stable structure.

Both the first soldering portion 26 and the second soldering portion 27 are soldering holes penetrating through the PCB 25, where the ends of the third connector 38 and the fourth connector 39 away from the battery unit 31 extend into the soldering holes and are then soldered, so that the third connector 38 and the fourth connector 39 are integrally connected to the hole walls of the soldering holes.

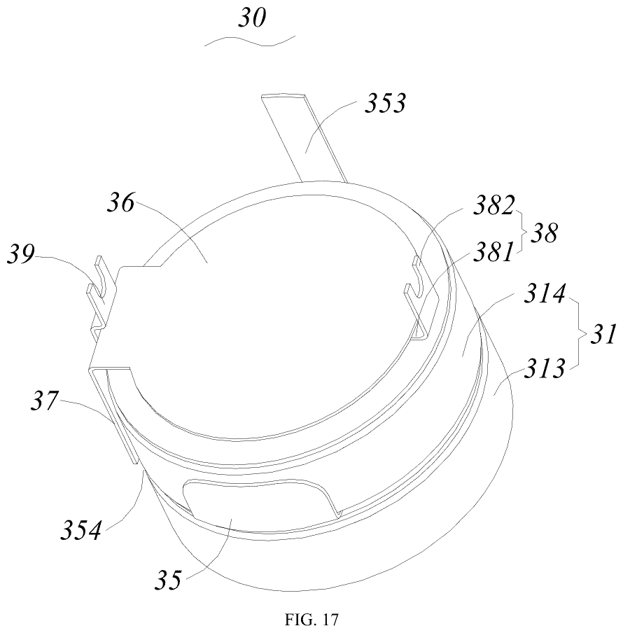

Specifically, referring to FIGS. 17-19, the third connector 38 comprises a third main body portion 381 and a third extension portion 382. The third main body portion 381 is connected to one end of the battery unit 31, facing towards the vibration motor 40. The overall shape of the third main body portion 381 is a board parallel to the PCB 25. The third extension portion 382 extends from the end of the third main body portion 381 towards the vibration motor 40, and the third extension portion 382 is integral with the third main body portion 381.

The fourth connector 39 comprises a fourth main body portion 391 and a fourth extension portion 392. The fourth main body portion 391 is connected to one end of the battery unit 31, away from the vibration motor 40. The overall shape of the fourth main body portion 391 is a board parallel to the PCB 25. The fourth extension portion 392 extends from the end of the fourth main body portion 391 along the side of the battery unit 31 towards the vibration motor 40, and the fourth extension portion 392 is positioned opposite to the third extension portion 382. The fourth extension portion 392 is integral with the fourth main body portion 391.

Similar to the first embodiment, referring to FIG. 10, the first fixing portion 51 is provided in one side facing the PCB 25 with a first avoidance groove 512 for housing one end of the third connector 38 away from the battery unit 31, and a second avoidance groove 513 for housing one end of the fourth connector 38 away from the battery unit 31. The first avoidance groove 512 and the second avoidance groove 513 provide space required for the soldering process of connecting the connectors to the PCB 25.

In a preferred embodiment of the present invention, the battery unit 31 comprises a first battery 313 and a second battery 314. The first battery 313 and the second battery 314 are distributed axially along the enclosure 10, with the first battery 313 positioned relative to the second battery 314 such that it is farther away from the PCB 25. The first battery 313 and the second battery 314 may be constituted by individual batteries, or be composed of a plurality of batteries in series.

The intermediate connector 35 connects the first battery 313 to the second battery 314. Specifically, the intermediate connector 35 comprises a battery fitting cavity that fits with the first battery 313, and the second battery 314 is connected to the intermediate connector 35 on the side opposite to the PCB 25. The intermediate connector 35 is made of metal materials, and the preferred method of connecting the first battery 313 to the intermediate connector 35 is soldering, while the preferred method of connecting the second battery 314 to the intermediate connector 35 is also soldering. When assembling the battery assembly 30, the first battery 313 is first placed into the battery fitting cavity, and then the second battery 314 is soldered to the intermediate connector 35. The battery fitting cavity serves the purpose of positioning the first battery 313 and enhancing the stability of the connection between the first battery 313 and the intermediate connector 35. The intermediate connector 35 may also be connected to the first battery 313 and the second battery 314 using a laser welding technique.

The intermediate connector 35 comprises a soldering lug 353 extending to between the PCB 25 and the vibration motor 40. The soldering lug 353 is used for soldering to the wires of the vibration motor 40 (wires not shown in FIGS).

One wire from the vibration motor 40 is soldered to a solder pad on the PCB 25, and the other wire is soldered to the soldering lug 353 of the intermediate connector 35. Since both ends of the battery unit 31 are electrically connected to the PCB 25, and the intermediate connector 35 connects the first battery 313 and the second battery 314, one end of the first battery 313 and the second battery 314 is electrically connected to the vibration motor 40 through the PCB 25, while the other end is electrically connected to the vibration motor 40 through the intermediate connector 35. This arrangement allows the first battery 313 and the second battery 314 to be selectively powered to the vibration motor 40 under the control of the control assembly 20. In addition, the two wires of the vibration motor 40 do not need to cross over the battery assembly 30 or pass through the space between the battery assembly 30 and the inner wall of the enclosure 10, making assembly of the vibration capsule more convenient.

Further, the soldering lug 353 passes through from the side of the PCB 25.

Further, the intermediate connector 35 comprises an avoidance opening 354 for avoiding contact with the fourth extension portion 392, thereby preventing a short circuit. The avoidance opening 354 is positioned radially on the intermediate connector 35 and communicates with an enclosure cavity of the battery unit.

The first insulating member 36 is positioned between the third main body portion 381 and the control assembly 20 and is used to prevent the battery unit 31, the third main body portion 381, and the electronic devices 24 of the control assembly 20 from coming into contact.

The second insulating member 37 is positioned between the fourth extension portion 392 and the battery unit 31. The second insulating member 37 prevents surface contact between the fourth extension portion 392 and the battery unit 31, so as to prevent a short circuit. The first insulating member 36 and the second insulating member 37 are integrally positioned to simplify the structure.

Specifically, the second insulating member 37 extends along the axial direction parallel to the enclosure 10, and one end of the second insulating member 37 is connected to the first insulating member 36. The other end of the second insulating member 37 is disposed on the side of the second battery 314, extending beyond the position of the first battery 313 to prevent contact between the second insulating member 37 and the intermediate connector 35. The second insulating member 37 is clamped between the battery unit 31 and the fourth extension portion 392, thereby securing the second insulating member 37 and the first insulating member 36 relative to the battery unit 31.

Overall, the vibrating motor 40, the control assembly 20, and the battery unit 31 are sequentially arranged along the axial direction of the enclosure 10, the second fixing portion 52 extends from one side of the first fixing portion 51 close to the control assembly 20 toward one side the control assembly 20 opposite to the vibrating motor 40, and the end of the second fixing portion 52 away from the first fixing portion 51 abuts against the battery unit 31. The above solution has the second fixing portion abut against the battery unit 31 to prevent the battery unit 31 from directly pressing onto the electronic devices 24 of the control assembly 20, so that false soldering or other faults between the electronic devices 24 and the PCB 25 may not be caused due to compression by battery pack, and the coaxial alignment between the vibrating motor 40, the motor bracket 50, and the battery component 30 cannot be affected by inconsistent height of the electronic devices 24, ensuring a fixed axial distance between the battery assembly 30 and the motor bracket 50.

The assembly process of the internal structure of the vibration capsule according to the second embodiment of the present invention is as follows:
(1) inserting the vibration motor 40 into the holding cavity 511 so that the vibration motor 40 is fixed to the motor bracket 50, then using adhesive to bond the vibration motor 40 to the motor bracket 50 to reinforce their connection; in the embodiments with an antenna, the antenna is also fixed to the motor bracket 50 at the same time;
(2) moving the control assembly 20 relative to the motor bracket 50, allowing the fixing rods 521 of the second fixing portion 52 to pass through the fixing grooves 212 of the PCB 25 until the end of the first fixing portion 51 abuts against the surface of the PCB 25; then, applying adhesive to secure the PCB 25 to the motor bracket 50;
(3) securing the assembly from step (2) and the battery assembly 30 in the appropriate position using a fixture; when the fixing rods 521 abut against the battery unit 31, it indicates that the assembly from step (2) and the battery assembly 30 are in the correct position;
(4) soldering the third connector 38 and the fourth connector 39 onto the PCB 25, and soldering the two wires of the vibration motor 40 to the solder pads and solder lug 353 on the PCB 25; this connects the vibration motor 40, the control assembly 20, the battery assembly 30, and the motor bracket 50 together.

The control assembly 20, the battery assembly 30, the vibration motor 40, and the motor bracket 50 are connected together, forming a cohesive structure that enhances the stability of the internal components of the vibration capsule. The assembled structure is then placed inside the enclosure 10 to complete the assembly of the entire vibration capsule. Since the two wires of the vibration motor 40 do not cross over the battery assembly 30, the width of the overall structure at the battery assembly 30 does not increase, making it easier for the overall structure to be installed into the enclosure 10.

The series of detailed descriptions set forth above are only specific descriptions of feasible embodiments of the present invention and are not intended to limit the scope of protection of the present invention. On the contrary, many modifications and variations are possible within the scope of the appended claims.

1. A vibration capsule comprising:
an enclosure;
a vibration motor;
a battery assembly; and
a control assembly;
wherein the vibration motor, the battery assembly and the control assembly are disposed within the enclosure, and the vibration motor and the battery assembly are electrically connected to the control assembly;
wherein the control assembly comprises:
a first PCB and a second PCB, disposed at opposite ends of the battery assembly;
a connecting structure that connects to the first PCB and the second PCB; and
a plurality of electronic devices disposed on one side of the first PCB away from the battery assembly, and/or on one side of the second PCB away from the battery assembly.

2. The vibration capsule of claim 1, wherein the first PCB and the second PCB are parallel to each other, the two ends of the connecting structure are respectively connected to the edges of the first PCB and the second PCB, and the connecting structure is disposed at a side of the battery assembly.

3. The vibration capsule of claim 1, wherein the connecting structure is a flexible PCB.

4. The vibration capsule of claim 1, wherein the battery assembly comprises a battery unit, a first connector connected to one end of the battery unit facing the first PCB, and a second connector connected to one end of the battery unit facing the second PCB, wherein the first connector is electrically connected to the first PCB and the second connector is electrically connected to the second PCB.

5. The vibration capsule of claim 4, wherein the first connector comprises a first main body portion that is parallel to the first PCB and first extension portions extending from two ends of the first main body portion in a direction away from the battery unit, wherein the first main body portion is connected to one end of the battery unit facing the first PCB, and the first extension portions are soldered to the first PCB; and
wherein the second connector comprises a second main body portion that is parallel to the second PCB and second extension portions extending from two ends of the second main body portion in a direction away from the battery unit, wherein the second main body portion is connected to one end of the battery unit facing the second PCB, and the second extension portions are soldered to the second PCB.

6. The vibration capsule of claim 5, wherein the first PCB is configured with two first through-holes that correspond one-to-one with the first extension portions, the first main body portion is fitted onto the first PCB, and the first extension portions extend into the first through-holes; and
wherein the second PCB is configured with two second through-holes that correspond one-to-one with the second extension portions, the second main body portion is fitted onto the second PCB, and the second extension portions extend into the second through-holes.

7. The vibration capsule of claim 5, wherein the battery unit comprises
a battery body and a cathode protrusion extending from one side of the battery body close to the first main body portion, toward the first main body portion; and
wherein the battery assembly further comprises an insulation ring that surrounds the cathode protrusion, and the insulation ring is disposed between the first main body portion and the battery body.

8. The vibration capsule of claim 1, wherein the vibration motor, the first PCB, the battery assembly, and the second PCB are arranged sequentially along the axial direction of the enclosure; and wherein the vibration capsule further comprises a motor bracket for securing the vibration motor, and the motor bracket is connected to the inner wall of the enclosure; and
wherein the motor bracket comprises a first fixing portion that fits with the vibration motor and a second fixing portion that fits with the first PCB.

9. The vibration capsule of claim 8, wherein one end of the first fixing portion facing the first PCB abuts against the first PCB, and the first fixing portion comprises a holding cavity for housing the vibration motor.

10. The vibration capsule of claim 8, wherein the second fixing portion comprises a plurality of fixing rods extending in a direction parallel to the axial direction of the enclosure, and the fixing rods surround the first PCB, wherein the outer periphery of the first PCB is configured with fixing grooves that fit with the fixing rods, and ends of the fixing rods away from the first fixing portion abut against the battery assembly.

11. The vibration capsule of claim 10, wherein the groove wall of the fixing grooves are arc-shaped.

12. The vibration capsule of claim 1, wherein the vibration capsule further comprises a motor bracket and an antenna, wherein the motor bracket is for securing the vibration motor, the antenna is fixed to the motor bracket, and the antenna is communicatively connected to the first PCB and/or the second PCB.

13. The vibration capsule of claim 12, wherein the antenna comprises a planar antenna and/or a wire antenna.

14. The vibration capsule of claim 13, wherein the motor bracket comprises an adhesive portion for adhering the planar antenna and/or an antenna groove for securing the wire antenna, and the antenna groove comprises a first antenna groove extending axially along the motor bracket and a second antenna groove disposed at one end of the motor bracket, away from the battery assembly.

15. The vibration capsule of claim 12, wherein the vibration capsule further comprises a motor cover disposed on one end of the motor bracket, away from the battery assembly.
